(19) United States
(12) Patent Application Publication
(10) Pub. No.: US 2006/0242740 A1
(43) Pub. Date: Oct. 26, 2006

(54) Method and device for surfactant activated Dip-Pen Nanolithography

(75) Inventors: Charles Patrick Collier, San Marino, CA (US); Seung-Yong Jung, Seoul (KR); Hyungil Jung, Pasadena, CA (US); Chiraj Dalal, Pasadena, CA (US); Steven Kuntz, Pasadena, CA (US); Raman Shah, Pasadena, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: California Institute of Technology, Pasadena, CA (US)

(21) Appl. No.: 11/201,562

(22) Filed: Aug. 10, 2005

Related U.S. Application Data
(60) Provisional application No. 60/600,453, filed on Aug. 11, 2004.

(51) Int. Cl. C30B 25/12

(52) U.S. Cl. 977/715

(57) ABSTRACT

A method for forming one or more nano-sized patterns using one or more molecule species overlying a substrate structure. In a preferred embodiment, the pattern or patterns relate to an array of biological molecules (e.g., DNA, small molecule(s), protein(s), ligand(s)). The method applies a probe tip (e.g., atomic force microscope probe (AFM probe)) within a vicinity of a first spatial region of a surface region of a substrate member, which is characterized by a first characteristic, e.g., hydrophobic, hydrophilic, partially hydrophobic, partially hydrophilic. In a specific embodiment, the probe tip is in a direction (e.g., normal, at an angle toward) toward the spatial region on the surface region. The method includes transferring one of more of a plurality of molecules characterized by a second characteristic through a fluid medium comprising one or more surfactant species (e.g., detergent) overlying the spatial region via the probe tip provided within the vicinity of the spatial region of the surface region. In a preferred embodiment, the one or more surfactant species causes one or more of the plurality of molecules characterized by the second characteristic to be deposited overlying the first spatial region. In a preferred embodiment, the first characteristic is different from the second characteristic.

### CROSS-REFERENCES TO RELATED APPLICATIONS

This application claims priority to U.S. Provisional Application No. 60/600,453 filed on Aug. 11, 2004, (Caltech Ref. No.: CIT-4178-P and Townsend and Townsend and Crew LLP Attorney Docket No.: 020859-006700US), which is hereby incorporated by reference herein in its entirety for all purposes.

### STATEMENT AS TO RIGHTS TO INVENTIONS MADE UNDER FEDERALLY SPONSORED RESEARCH OR DEVELOPMENT

N/A

### BACKGROUND OF THE INVENTION

The present invention relates generally to printing techniques. More particularly, the present invention provides a method and system for dispensing one or more entities using a nano-lithography technique. Merely by way of example, the invention has been applied to dispensing one or more patterns of monolayers of materials using an atomic force microscope tip(s), commonly called Dip-Pen Nanolithography (“DPN”), which is a direct-write printing technique. But it would be recognized that the invention has a much broader range of applicability.

As time progressed, a variety of printing techniques have been developed. From the early days, printing relied upon certain basic elements including ink, paper, and machined surfaces, which bear text and/or images in relief that were transferred onto the paper. Ink coated steel plates were often used as the surfaces that transferred the text and/or images onto paper. Other printing techniques developed includes lithography, typography, xylography, and conventional forms of ink jet printing, often used with computer applications.

Other types of printing techniques have been used to form one or more arrays of biological materials (including molecular probes) onto surfaces of substrates. The array of biological materials formed on the substrate is often called a “biological chips.” Certain types of biological chips include certain spatial regions on the order of about tens of microns in scale. These chips have been useful to determine whether one or more target molecules interact with one or more probe molecules on the biological chip.

Conventional biological chips have been used for certain types of screening techniques. Such screening techniques can be useful for determining information about either or both the probe and/or target molecules. As merely an example, a specific library of peptides used as probes can screen for one or more drugs. The peptides can be exposed to a receptor, and those probes that bind to the receptor can be identified using certain techniques. Although highly successful, these techniques are often limited in an ability to create smaller and smaller regions of biological materials.

Various limitations exist with these conventional techniques. For example, these techniques often have limited resolution and can be reduced to certain spatial sizes. Additionally, certain types of materials are often difficult and/or even incompatible with applications to other types of substrate structures. For example, hydrophobic surfaces on substrate structures often cannot be used as a printing medium for “water based” molecular entities. These and other limitations are described throughout the present specification and more particularly below.

From the above, it is seen that improved technique for printing patterns of chemical and/or biological entities in a spatial manner are desired.

### BRIEF SUMMARY OF THE INVENTION

According to the present invention, techniques for printing one or more patterns using mono-layers of materials are provided. More particularly, the present invention provides a method and system for dispensing one or more entities using a nano-lithography technique. Merely by way of example, the invention has been applied to dispensing one or more patterns of mono-layers of materials using an atomic force microscope tip(s), commonly called Dip-Pen Nanolithography (“DPN”), which is a direct-write printing technique. But it would be recognized that the invention has a much broader range of applicability. For example, the invention can be applied to formation of patterns using biological materials, chemical materials, metal materials, polymer materials, solid state materials, small molecules (e.g., molecule structures of 100 atoms and less), dendrimers, DNA, proteins, semiconductors, insulators, organic thin films, inorganic thin films, any combination of these, and the like. Additionally, the method and applications can be from a variety of different fields such as electronics, semiconductor, inorganic chemistry, organic chemistry, life sciences, medical and diagnostics, life style, security, petroleum, agricultural, biotechnology, financial, molecular interaction, and others.

In a specific embodiment, the present invention provides a method for forming one or more molecular patterns, using one or more surfactant entities, overlying a substrate structure. The method includes applying a probe tip within a vicinity of a first spatial region of a surface region of a substrate member. The method also includes maintaining a volume of fluid including a plurality of molecules and a plurality of surfactant species coupled to the probe tip. In a specific embodiment, the volume of fluid attaches to the probe or region of the probe using certain forces (e.g., Vanderwaals) between the fluid and the probe member. The method causes a transfer of one of more of the plurality of molecules, using one or more surfactant species, overlying the spatial region via the probe tip provided within the vicinity of the spatial region of the surface region.

In an alternative specific embodiment, the present invention provides a method for forming one or more nano-sized patterns using one or more molecule species overlying a substrate structure. In a preferred embodiment, the pattern or patterns relate to an array of biological molecules (e.g., DNA, small molecule(s), protein(s), ligand(s), polypeptides, polysaccharides). The method applies a probe tip (e.g., atomic force microscope probe (AFM probe)) within a vicinity of a first spatial region of a surface region of a substrate member, which is characterized by a first characteristic, e.g., hydrophobic, hydrophilic, partially hydrophobic, partially hydrophilic. In a specific embodiment, the probe tip is in a direction (e.g., normal, at an angle toward) toward the spatial region on the surface region. The method includes transferring one of more of a plurality of molecules characterized by a second characteristic through a fluid medium comprising one or more surfactant species (e.g., detergent) overlying the spatial region via the probe tip provided within the vicinity of the spatial region of the surface region. In a preferred embodiment, the one or more surfactant species causes one or more of the plurality of molecules characterized by the second characteristic to be deposited overlying the first spatial region. In a preferred embodiment, the first characteristic is different from the second characteristic. The method includes moving the probe tip from the vicinity of the first spatial region to a vicinity of a second spatial region on the surface region while continuing to deposit one or more of the plurality of molecules characterized by the second characteristic through the fluid medium comprising one or more surfactant molecules.

In yet an alternative embodiment, the present invention provides a system for forming one or more molecular patterns using one or more molecule species overlying a substrate structure. The system has a stage assembly operable to maintain a substrate member comprising a surface region. The system has a sample reservoir operably coupled to the stage assembly. In a preferred embodiment, the sample reservoir has a fluid medium including a plurality of molecules having a second characteristic and a plurality of surfactant species mixed within the plurality of molecules. The system also has a probe tip operably coupled to the stage. In a preferred embodiment, the probe tip is adapted to transfer one or more of the plurality of molecules including one or more of the surfactant species through a portion of the fluid medium from the fluid medium in the sample reservoir. In a specific embodiment, the probe tip is also adapted to apply the probe tip within a vicinity of a first spatial region of the surface region of the substrate member and adapted to transferring one of more of the plurality of molecules through a portion of the fluid medium comprising one or more surfactant species overlying the spatial region via the probe tip provided within the vicinity of the spatial region of the surface region. In a preferred embodiment, the one or more surfactant species causes one or more of the plurality of molecules characterized by the second characteristic to be deposited overlying the first spatial region.

Numerous benefits can be achieved using the present invention over conventional techniques. As merely an example, the present invention can provide for an array of molecules having a spot size of about 70 nm and less according to a specific embodiment. Additionally, the present method and system may be capable of depositing one or more molecules, which may be hydrophilic, to a surface that is partially hydrophobic and/or entirely hydrophobic according to a specific embodiment. Furthermore, the present method and system may be implemented using conventional surfactant technologies on a wide variety of Dip-Pen techniques according to a specific embodiment. The present techniques can also lead to improved throughput, efficiency, and yield according to a specific embodiment. Still further, the present methods and systems provides for one or more self-assembled monolayers of deposited materials overlying a substrate surface (which were previously incompatible with each other) according to a specific embodiment. Depending upon the embodiment, one or more of these benefits may be achieved. These and other benefits are described throughout the present specification and more particularly below.

From the above, it is seen that techniques for improving ways to manufacturing probe designs for microscopes are highly desired.

### BRIEF DESCRIPTION OF THE DRAWINGS

FIG. 1 is a simplified diagram of a Dip-Pen nanolithography system according to an embodiment of the present invention;

FIG. 2 is a simplified diagram of a probe tip for Dip-Pen nanolithography according to an embodiment of the present invention;

FIG. 3 is a simplified diagram of a computer system according to an embodiment of the present invention;

FIG. 3A is a simplified block diagram of a computer system according to an embodiment of the present invention;

FIG. 4 is a simplified flow diagram illustrating a method for printing one or more patterns using a Dip-Pen according to an embodiment of the present invention;

FIG. 5 is a simplified diagram illustrating a method for dispensing an ink medium using a Dip-Pen and surfactant according to an embodiment of the present invention;

FIG. 6 is a simplified diagram illustrating a method for dispensing an ink medium using a Dip-Pen and surfactant according to an alternative embodiment of the present invention;

FIG. 7 is a simplified diagram illustrating two different maleimide entities provided for an ink medium according to embodiments of the present invention;

FIGS. 8 through 10 are simplified diagram illustrating experimental results according to embodiments of the present invention; and

FIGS. 11 through 14 are simplified diagram illustrating experimental results according to alternative embodiments of the present invention

### DETAILED DESCRIPTION OF THE INVENTION

According to the present invention, techniques for printing one or more patterns using mono-layers of materials are provided. More particularly, the present invention provides a method and system for dispensing one or more entities using a nano-lithography technique. Merely by way of example, the invention has been applied to dispensing one or more patterns of mono-layers of materials using an atomic force microscope tip(s), commonly called Dip-Pen Nanolithography (“DPN”), which is a direct-write printing technique. But it would be recognized that the invention has a much broader range of applicability. For example, the invention can be applied to formation of patterns using biological materials, chemical materials, metal materials, polymer materials, solid state materials, small molecules (e.g., molecule structures of 100 atoms and less), dendrimers, DNA, proteins, semiconductors, insulators, organic thin films, inorganic thin films, any combination of these, and the like. Additionally, the method and applications can be from a variety of different fields such as electronics, semiconductor, inorganic chemistry, organic chemistry, life sciences, life style, security, petroleum, agricultural, biotechnology, financial, and others.

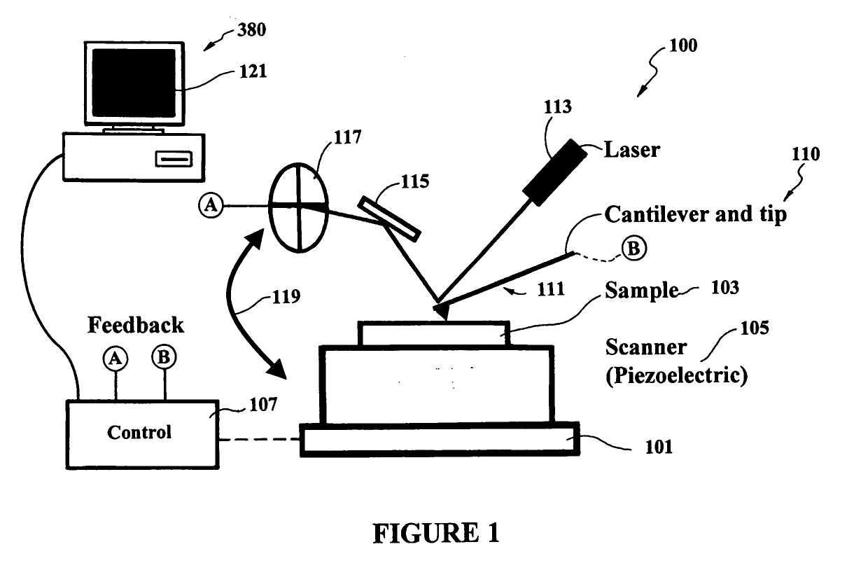

FIG. 1 is a simplified diagram of a Dip-Pen nanolithography system 100 according to an embodiment of the present invention. This diagram is merely an example, which should not unduly limit the scope of the claims herein. One of ordinary skill in the art would recognize many variations, alternatives, and modifications. As shown, the system is preferably a scanning system 100 according to a specific embodiment. This diagram is merely an example, which should not unduly limit the scope of the claims herein. One of ordinary skill in the art would recognize many other modifications, alternatives, and variations. As shown, the present system 100 includes a mobile stage 101, which has x-y-z movement capability. The stage can be moved with a tolerance of less than 40 microns for sample positioning and when used for alignment can be moved with a tolerance of <1 nm. A sample 103 is placed on the stage. Additionally, the stage can provide a scanning speed ranging from about 0.1 Hz to about 12.2 Hz and/or others according to a specific embodiment. In a specific embodiment, the stage relative to the probe can be moved a rate of about 0.0004 and greater millimeters per second according to a specific embodiment, but can also be at other rates depending upon the specific embodiment. Of course, there can be other variations, modifications, and alternatives.

Depending upon the application, the sample can include a substrate according to a specific embodiment. Additionally, the sample can be a plurality of substrates according to a specific embodiment. Depending upon the embodiment, the substrate can be made of a single layer or multiple layers. The substrate can be homogeneous and/or made of a variety of different materials according to a specific embodiment. The substrate can be a semiconductor (e.g., silicon, germanium Group III/V materials, semiconductor polymer material, Indium Tin Oxide, a conductor (e.g., metal, doped semiconductor, conductive plastic or polymer, ITO, or an insulator (e.g., glass, ceramic, polymer, plastic, dielectric material, mica), or any combination of these, depending upon the specific embodiment. In a preferred embodiment, the substrate is often a glass or quartz plate, which is suitable for biological reactions. The glass plate also has a suitable rigidity and substantially flat upper surface region, although there can be other variations, modifications and alternatives.

In a specific embodiment, the sample can be maintained in a desired environment. In a specific embodiment, the desired environment includes liquids, fluids (e.g., liquid and/or vapor), air, inert gas environments, or in vacuum and at specific temperatures (cryogenic, room temperature, warm to extremely high temperatures), depending upon the specific embodiment. Additionally, the environment can also be subjected to a determined relative humidity according to a specific embodiment. The relative humidity can range from about 22% to about 92% depending upon the specific embodiment. In a specific embodiment, the system also can maintain a substrate temperature ranging from about 23° C. to about 24° C. Of course, there can be other variations, modifications, and alternatives.

In a specific embodiment, the system also includes a tapping mode atomic force microscope (“AFM”) 110. Depending upon the specific embodiment, the probe tip can be maintained at a contact force overlying a portion of the substrate at about 9 nano-Newton to about 25 nano Newton. Alternatively, the probe tip can be maintained at a contact force overlying the portion of the substrate greater than about 9 nano Newton, but can also be at other one or more forces according to a specific embodiment. In a specific embodiment, the AFM 110 has various elements such as probe 111, a cantilever to support the probe, which is coupled to a piezo-electric stack 105. Such piezo-stack provides for dithering and z-motion of the cantilever. The AFM also includes a driving signal, which is coupled to control electronics 107 for signal detection and correction. Preferably, probe has a pyramidal shape according to a specific embodiment. In the present embodiment, the tip includes the nanotube structure according to a specific embodiment. Specific details of the present probe can be found throughout the present specification and more particularly below.

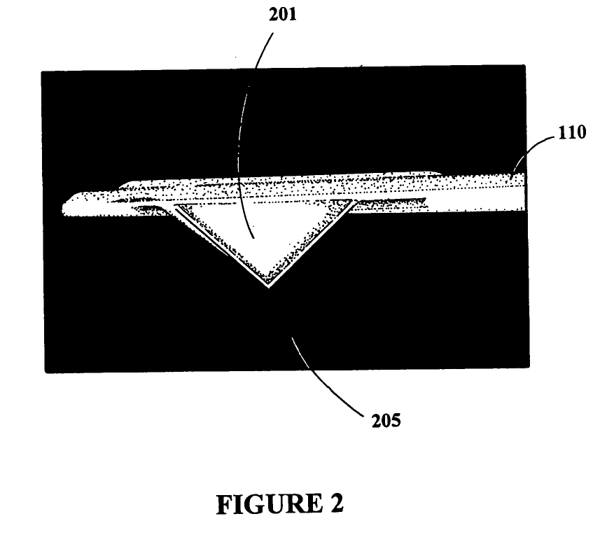

As shown, FIG. 2 is a simplified diagram of a probe tip for Dip-Pen nanolithography according to an embodiment of the present invention. This diagram is merely an example, which should not unduly limit the scope of the claims herein. One of ordinary skill in the art would recognize many variations, alternatives, and modifications. As shown, the AFM probe 201 is characterized by a tip structure 205. The tip structure is often made of silicon bearing species. The silicon bearing species is from a silicon wafer and/or other like material. The tip structure has a pyramid-like shape that protrudes from a base to an end, as shown. In a specific embodiment, the tip size ranges from about 20 to about 60 nanometers and is preferably less than about 30 nm. In a specific embodiment, the tip is coated with a silicon nitride bearing material, but can be others. Depending upon the specific embodiment, the tip structure may include a nanotube base structured coupled thereon. Of course, there can be other variations, modifications, and alternatives.

Referring back to FIG. 1, the AFM also includes a laser source 113, which is directed to the cantilever or probe. The laser source is used as a position detector, which provides photons that scatter off of the cantilever and/or probe. Such scattered photons are detected by way of photodetector 117, which is coupled to control electronics 107. The control electronics provide feedback 119 to the stage according to a specific embodiment. The control electronics provide feedback 119 to the probe according to a specific embodiment. Feedback can also be provided to both the stage and cantilever according to a specific embodiment. Depending upon the embodiment, the AFM may be coupled to an inverted optical microscope (not shown) according to a specific embodiment. Additionally, the system also includes one or more sample reservoirs 123 according to a specific embodiment. In a preferred embodiment, the reservoir includes at least a plurality of molecules to be dispensed and one or more surfactant species, which enhance transfer of the molecules onto a sample substrate. The reservoir is operably coupled to the probe tip, which is insertable within a portion of the fluid medium provided in the reservoir.

Depending upon the specific embodiment, the system is overseen and controlled by one or more computer systems, including a microprocessor and/controllers. In a preferred embodiment, the computer system or systems include a common bus, oversees and performs operation and processing of information. The system also has a display 121, which can be a computer display, coupled to the control system 380, which will be described in more detail below. Of course, there can be other modifications, alternatives, and variations. Further details of the present system are provided throughout the specification and more particularly below.

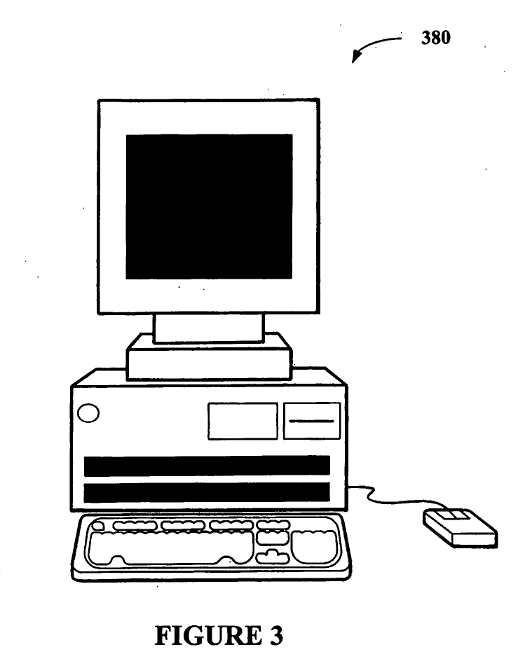

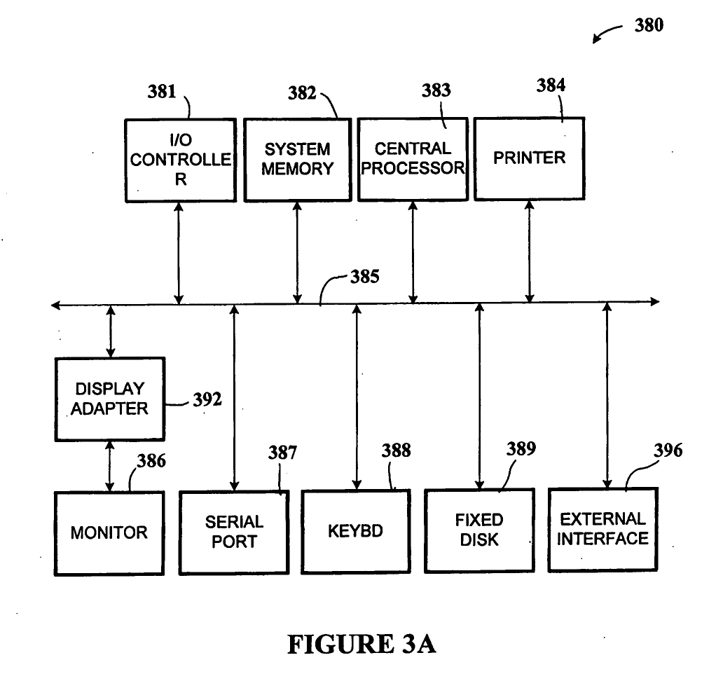

FIG. 3 is a simplified diagram of a computer system 300 that is used to oversee the system of FIG. 1 according to an embodiment of the present invention. This diagram is merely an example, which should not unduly limit the scope of the claims herein. One of ordinary skill in the art would recognize many other modifications, alternatives, and variations. As shown, the computer system includes display device, display screen, cabinet, keyboard, scanner and mouse. Mouse and keyboard are representative “user input devices.” Mouse includes buttons for selection of buttons on a graphical user interface device. Other examples of user input devices are a touch screen, light pen, track ball, data glove, microphone, and so forth.

The system is merely representative of but one type of system for embodying the present invention. It will be readily apparent to one of ordinary skill in the art that many system types and configurations are suitable for use in conjunction with the present invention. In a preferred embodiment, computer system 300 includes a Pentium™ class based computer, running Windows™ NT operating system by Microsoft Corporation or Linux based systems from a variety of sources. However, the system is easily adapted to other operating systems and architectures by those of ordinary skill in the art without departing from the scope of the present invention. As noted, mouse can have one or more buttons such as buttons. Cabinet houses familiar computer components such as disk drives, a processor, storage device, etc. Storage devices include, but are not limited to, disk drives, magnetic tape, solid-state memory, bubble memory, etc. Cabinet can include additional hardware such as input/output (I/O) interface cards for connecting computer system to external devices external storage, other computers or additional peripherals, which are further described below.

FIG. 3A is a more detailed diagram of hardware elements in the computer system according to an embodiment of the present invention. This diagram is merely an example, which should not unduly limit the scope of the claims herein. One of ordinary skill in the art would recognize many other modifications, alternatives, and variations. As shown, basic subsystems are included in computer system 300. In specific embodiments, the subsystems are interconnected via a system bus 385. Additional subsystems such as a printer 384, keyboard 388, fixed disk 389, monitor 386, which is coupled to display adapter 392, and others are shown. Peripherals and input/output (I/O) devices, which couple to I/O controller 381, can be connected to the computer system by any number of means known in the art, such as serial port 387. For example, serial port 387 can be used to connect the computer system to a modem 391, which in turn connects to a wide area network such as the Internet, a mouse input device, or a scanner. The interconnection via system bus allows central processor 383 to communicate with each subsystem and to control the execution of instructions from system memory 382 or the fixed disk 389, as well as the exchange of information between subsystems. Other arrangements of subsystems and interconnections are readily achievable by those of ordinary skill in the art. System memory, and the fixed disk are examples of tangible media for storage of computer programs, other types of tangible media include floppy disks, removable hard disks, optical storage media such as CD-ROMS and bar codes, and semiconductor memories such as flash memory, read-only-memories (ROM), and battery backed memory.

Although the above has been illustrated in terms of specific hardware features, it would be recognized that many variations, alternatives, and modifications can exist. For example, any of the hardware features can be further combined, or even separated. The features can also be implemented, in part, through software or a combination of hardware and software. The hardware and software can be further integrated or less integrated depending upon the application. Further details of certain methods according to the present invention can be found throughout the present specification and more particularly below.

A method for forming one or more patterns using a Dip-Pen and surfactant according to an embodiment of the present invention may be outlined as follows:

1. Provide a substrate member, e.g., glass cover sheet;

2. Dip probe tip (e.g., atomic force microscope probe (AFM probe)) into ink solution, including a surfactant species;

3. Transfer ink solution onto probe tip to form a volume of fluid coupled to the probe tip;

4. Align the probe tip within a vicinity of a first spatial region of a surface region of the substrate member, which is characterized by a first characteristic, e.g., hydrophobic, hydrophilic, partially hydrophobic, partially hydrophilic;

5. Applies the probe tip within the vicinity of the first spatial region of the surface region of the substrate member;

6. Transfer one of more of a plurality of molecules characterized by a second characteristic through a fluid medium comprising the one or more surfactant species (e.g., detergent) overlying the spatial region via the probe tip provided within the vicinity of the spatial region of the surface region;

7. Move the probe tip from the vicinity of the first spatial region to a vicinity of a second spatial region on the surface region;

8. Continue to deposit one or more of the plurality of molecules characterized by the second characteristic through the fluid medium comprising one or more surfactant molecules;

9: Optionally, repeat any single and/or combination of the above steps; and

10. Perform other steps, as desired.

The above sequence of steps provides a method according to an embodiment of the present invention. As shown, the method uses a combination of steps including a way of using a surfactant species to facilitate transfer of one or more molecules from an AFM probe tip or like probe tip onto a selected spatial region of a substrate member according to a specific embodiment. Other alternatives can also be provided where steps are added, one or more steps are removed, or one or more steps are provided in a different sequence without departing from the scope of the claims herein. Additionally, the present method can be applied to other applications that are not for AFM techniques. Further details of the present method can be found throughout the present specification and more particularly below.

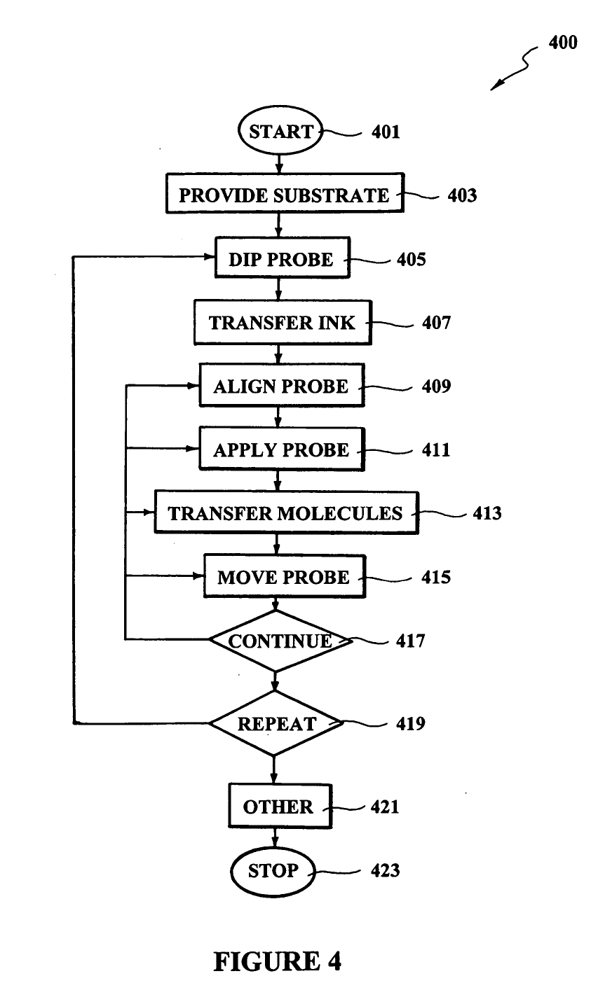

FIG. 4 is a simplified flow diagram 400 illustrating a method for printing one or more patterns using a Dip-Pen according to an embodiment of the present invention. This diagram is merely an example, which should not unduly limit the scope of the claims herein. One of ordinary skill in the art would recognize many variations, alternatives, and modifications. As shown, the method begins with start, step 401. In a specific embodiment, the method provides (step 403) a substrate member, e.g., glass cover sheet. Depending upon the embodiment, the substrate can be made of a single layer or multiple layers. The substrate can be homogeneous and/or made of a variety of different materials according to a specific embodiment. The substrate can be a semiconductor (e.g., silicon, germanium Group III/V materials, semiconductor polymer material, a conductor (e.g., metal, doped semiconductor, conductive plastic or polymer, ITO), or an insulator (e.g., glass, ceramic, polymer, plastic, dielectric material, mica), or any combination of these, depending upon the specific embodiment. In a preferred embodiment, the substrate is often a glass or quartz plate, which is suitable for biological reactions. The glass plate also has a suitable rigidity and substantially flat upper surface region, although there can be other variations, modifications and alternatives.

In a specific embodiment, surfaces of the substrate are subjected to a cleaning and drying process. In a specific embodiment using a glass cover slip, the method uses a Piranha solution, which are often used to remove organic residues. As merely an example, the piranha solution is a 3:1 mixture of sulfuric acid and 30% hydrogen peroxide according to a specific embodiment, although it can vary depending upon the specific embodiment. The solution can be mixed before application or directly applied to the material, applying the sulfuric acid first, followed by the peroxide. (Note: Piranha solutions are energetic and may result in explosion or skin burns if not handled with extreme caution). Once cleaned, the substrate is subjected to a drying process according to a specific embodiment. The drying process often uses a bake and/or other techniques to substantially eliminate moisture from the substrate member according to a specific embodiment. Of course, there are other variations, modifications, and alternatives.

In a specific embodiment, the method transfers an ink solution, including a surfactant, for dispensing using a probe tip, which includes a tip structure. The tip structure is often made of silicon bearing species. The silicon bearing species is from a silicon wafer and/or other like material. The tip structure has a pyramid-like shape that protrudes from a base to an end, as shown. In a specific embodiment, the tip size ranges from about 20 to about 60 nanometers and is preferably less than about 30 nanometers. In a specific embodiment, the tip is coated with a silicon nitride bearing material, but can be others. Depending upon the specific embodiment, the tip structure may include a nanotube base structured coupled thereon. Of course, there can be other variations, modifications, and alternatives.

In a specific embodiment, the method dips (step 405) the tip into the ink solution, including a surfactant species. Depending upon the specific embodiment, the ink solution includes at least one or more molecular species to be transferred. The one or more molecular species can include biological materials, chemical materials, metal materials, polymer materials, solid state materials, small molecules (e.g., molecule structures of 100 atoms and less), dendrimers, DNA, proteins, semiconductors, insulators, organic thin films, inorganic thin films, any combination of these, and the like. Additionally, the method and applications can be from a variety of different fields such as electronics, semiconductor, inorganic chemistry, organic chemistry, life sciences, life style, security, petroleum, agricultural, biotechnology, financial, and others. Of course, there can be other variations, modifications, and alternatives.

In a preferred embodiment, the ink solution includes a surfactant entity and/or species. In a specific embodiment, the surfactant is a detergent, which is capable of attaching to one or more portions of the one or molecules being disposed. In a specific embodiment, the detergent is also capable of being attached and/or attracted to one or more portions of a surface region of the substrate. In a specific embodiment, the surfactant can be any suitable entity such as Tween 20. Of course, there can be other variations, modifications, and alternatives.

In a specific embodiment, the method transfers (step 407) the ink solution onto probe tip to form a volume of fluid coupled to the probe tip. Often times, the transfer occurs using cohesive forces within the fluid and between the probe tip and the fluid, which assists with the transfer of the fluid volume to the probe according to an embodiment of the present invention. Depending upon the specific embodiment, the transfer of the fluid is unaffected by the presence of the surfactant species. Of course, the surfactant may slightly retard or even enhance the transfer of the fluid volume according to a specific embodiment.

As shown in step 409, the method aligns the probe tip (e.g., atomic force microscope probe (AFM probe)) within a vicinity of a first spatial region of a surface region of the substrate member, which is characterized by a first characteristic, e.g., hydrophobic, hydrophilic, partially hydrophobic, partially hydrophilic. The method applies (step 411) the probe tip within the vicinity of the first spatial region of the surface region of the substrate member. Upon application, which occurs upon direct contact with the substrate or close proximity to the surface of the substrate, the method transfers (step 413) one of more of a plurality of molecules characterized by a second characteristic through a fluid medium comprising the one or more surfactant species (e.g., detergent) overlying the spatial region via the probe tip provided within the vicinity of the spatial region of the surface region.

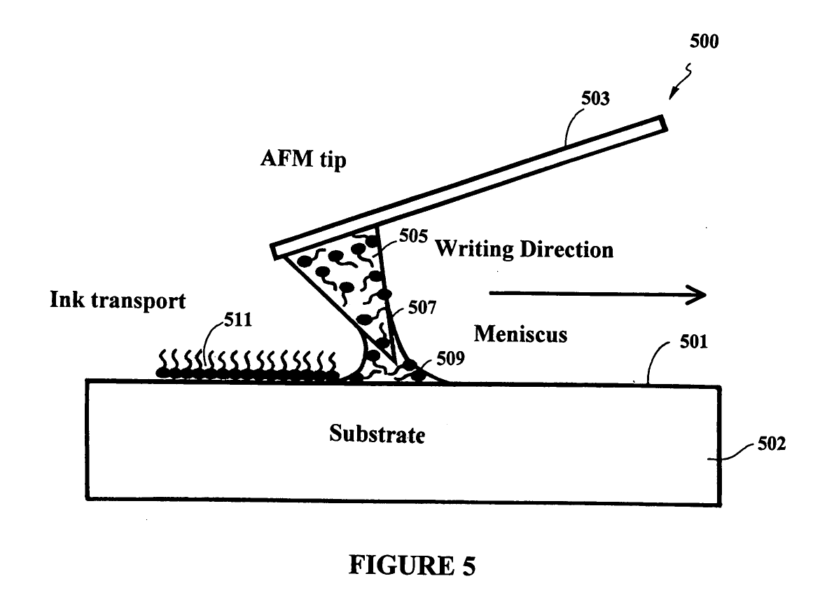

Referring to FIG. 5, we have illustrated an example of a probe tip dispensing 400 one or more molecules in a pattern according to a specific embodiment. This diagram is merely an example, which should not unduly limit the scope of the claims herein. One of ordinary skill in the art would recognize many variations, alternatives, and modifications. As shown, the method provides a substrate member 502, which includes a surface region 501. The surface region may be subjected to one or more overlying mono-layers according to an embodiment of the present invention. As shown, the method forms a mono-layer of molecular species 511 according to a specific embodiment. Each of the molecules includes a first end attachable to a portion of the surface region and a second end, which is attachable to another molecule and/or species according to a specific embodiment. As shown, the probe 503, includes cantilever member coupled to a probe tip 505, which has an end 507 region. The end region is pointed toward the surface region in a specific embodiment. The end region may be normal or within an angle ranging from greater than about 0 Degrees to less than about 180 degrees from an imaginary line parallel to the surface region according to a specific embodiment. The probe, including a volume of fluid, is dispensed 509 overlying a spatial region of the surface region according to a specific embodiment. As the probe tip is moved from a first region to a second region (which is indicated by the “Writing Direction”), the molecules within the fluid continue to dispense across selected portions of the surface region according to a specific embodiment. Of course, there can be other variations, modifications, and alternatives.

In a preferred embodiment, the volume of fluid includes the surfactant species, which facilitates transfer and attachment of the one or more molecules in the fluid volume. The surfactant has been mixed with into the volume of fluid and facilitates the transfer and application of the one or more molecules onto selected portions of the surface region. Of course, there can be other variations, modifications, and alternatives.

As further shown, the method includes moving (step 415) the probe tip from the vicinity of the first spatial region to a vicinity of a second spatial region on the surface region. Referring again to FIG. 5 and step 417, the method continues to deposit one or more of the plurality of molecules characterized by the second characteristic through the fluid medium comprising one or more surfactant molecules. In a specific embodiment, the movement of the probe is made at a suitable speed and rate, which may be consistent and/or vary with respect to time. The probe movement rate, also called scanning rate, can range from about 0.4 μm/sec to about 40 μm/sec according to a specific embodiment. The rate is preferably about 10 μm/sec and greater according to a specific embodiment. Of course, one of ordinary skill in the art would recognize other variations, modifications, and alternatives.

Depending upon the specific embodiment, the present method can also have other steps added, repeated, combined, and/or any combination of the above, and others outside of the present specification. The method, optionally, repeats (step 419) any single and/or combination of the above steps according to a specific embodiment. Depending upon the embodiment, other steps can also be added, inserted, and/or performed (step 412) on the present substrate, including the mono-layer according to a specific embodiment. In a specific embodiment, the present method stops, at step 423. Of course, there can be other variations, modifications, and alternatives.

The above sequence of steps provides a method according to an embodiment of the present invention. As shown, the method uses a combination of steps including a way of using a surfactant species to facilitate transfer of one or more molecules from an AFM probe tip or like probe tip onto a selected spatial region of a substrate member according to a specific embodiment. Other alternatives can also be provided where steps are added, one or more steps are removed, or one or more steps are provided in a different sequence without departing from the scope of the claims herein. Additionally, the present method can be applied to other applications that are not for AFM techniques. Alternative methods according to the present invention can be found throughout the present specification and more particularly below.

A method for applying one or more specific maleimide entity molecules coupled to a cover glass according to an embodiment of the present invention may be outlined as follows:

1. Provide a glass cover slip;

2. Clean cover slip with Piranha solution;

3. Dry in bake oven for 25 to 30 minutes at a temperature of about 80 Degrees Celsius or greater;

4. Form a mono-layer coating of silane (e.g., MPTMS) overlying a surface of the glass cover slip at a temperature of about 110 Degrees Celsius, where the silane group forms overlying the glass surface;

5. Subject a tip having a silicon nitride material of a probe to a fluid including maleimide and surfactant entity to hold a fluid volume of the fluid on the tip of the probe;

6. Apply tip of probe using an AFM tapping mode on a portion of the surface of the cover glass;

7. Transfer one or more molecules from the fluid to the portion of the surface;

8. Continue steps (5) through (7) to form a pattern on a selected portion of the surface of the cover glass;

9. Apply one or more other molecules on unpatterned region of the surface of the cover glass; and

10. Apply one or more bio-functional species onto the patterned; and

11. Perform other steps as desired.

The above sequence of steps provides a method according to an embodiment of the present invention. As shown, the method uses a combination of steps including a way of using a surfactant species to facilitate transfer of one or more molecules of maleimde from an AFM probe tip or like probe tip onto a selected spatial region of a substrate member according to a specific embodiment. Other alternatives can also be provided where steps are added, one or more steps are removed, or one or more steps are provided in a different sequence without departing from the scope of the claims herein. Additionally, the present method can be applied to other applications that are not for AFM techniques. Further details of the present method according to the present invention can be found throughout the present specification and more particularly below.

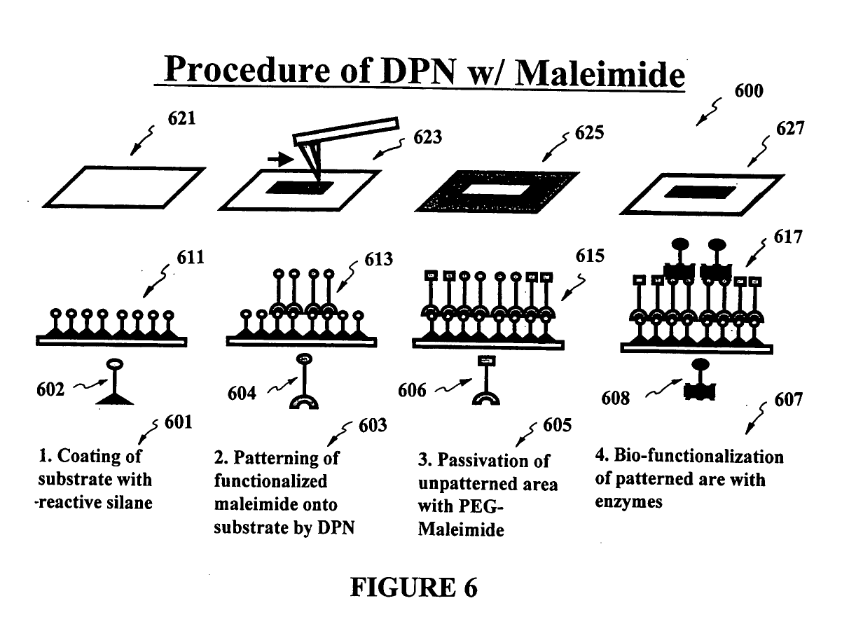

FIG. 6 is a simplified diagram 600 illustrating a method for dispensing an ink medium using a Dip-Pen and surfactant according to an alternative embodiment of the present invention. This diagram is merely an example, which should not unduly limit the scope of the claims herein. One of ordinary skill in the art would recognize many variations, alternatives, and modifications. As shown, the method includes steps of coating a substrate with reactive silane molecules, which are illustrated by reference numerals 601, 611, and 621. Each of the reactive molecules 602 has a first end, which attaches to a portion of the substrate, and a second end, which will be attached to a functionalized maleimide, according to an embodiment of the present invention.

Referring again to FIG. 6, the method includes patterning (step 603) of functional maleimide onto a selected portion of the substrate. As shown, each functional maleimide 604 has a first end, which attaches to a reactive silane, and a second end according to a specific embodiment. The patterning is also illustrated using a side-view illustration 613 and a probe tip illustration 623 according to a specific embodiment. Of course, there can be other variations, modifications, and alternatives.

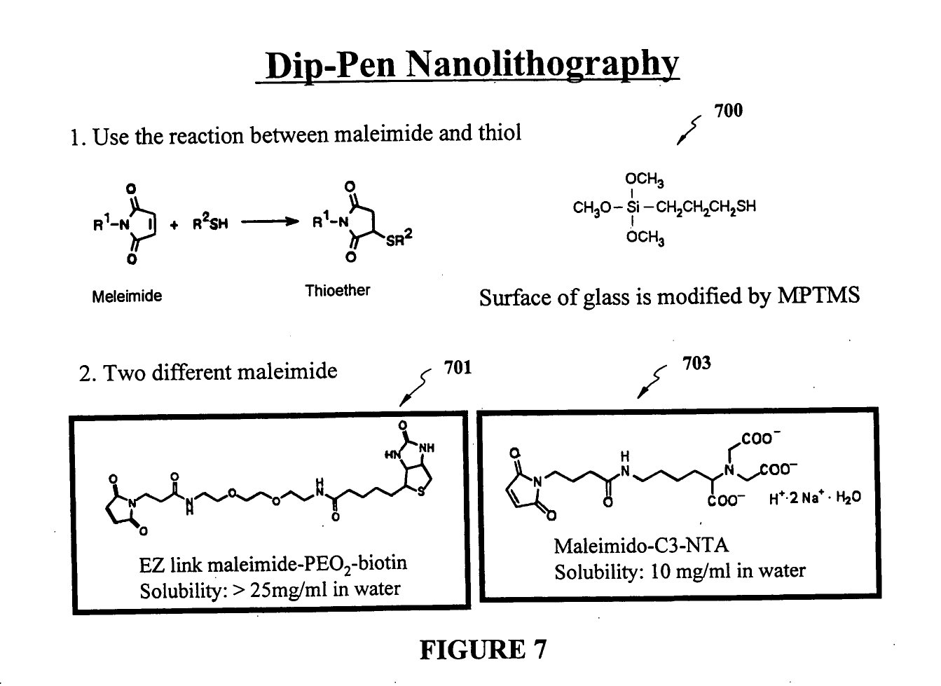

As merely an example, FIG. 7 is a simplified diagram illustrating two different maleimide entities 700 provided for an ink medium according to embodiments of the present invention. This diagram is merely an example, which should not unduly limit the scope of the claims herein. One of ordinary skill in the art would recognize many variations, alternatives, and modifications. As shown, maleimide includes a first entity 701 (EZ link maleimide-PEO₂-biotin (which has a solubility of >25 milligrams/milliliter in water) and a second entity 703, which is maleimide-C3-NTA (which has a solubility of 10 milligrams/milliliter in water) according to a specific embodiment. Additionally, FIG. 7 illustrates a reaction between maleimide and thiol according to an embodiment of the present invention. As shown, the glass surface has been modified by MPTMS according to a specific embodiment. Of course, there can be other variations, modifications, and alternatives.

In a specific embodiment, which refers back to FIG. 6, the method includes passivating an unpatterned area with PEG-maliemide molecules, step 605. Each of the molecules 606 includes a first end, which attaches to a functionalized maleimide, and a second end, which is non-reactive, according to a specific embodiment. In a specific embodiment, the molecules can be applied (step 625) using a batch wet process, dry process, spray process, and/or any combination of these, and the like. That is, the PEG molecules selectively attach to the unpatterned area to form a resulting array structure 615 according to a specific embodiment. Of course, there can be other variations, modifications, and alternatives.

The method performs a bio-functionalization process (step 607 of the pattered regions with one or more enzymes according to a specific embodiment. Each of the enzymes 608 has a first end, which couples to the functionalized maleimde, and second end, which may or may not be reactive, according to a specific embodiment. The enzymes can be applied (step 627) using a batch wet process, dry process, spray process, and/or any combination of these, and the like. That is, the enzymes selectively attach to the functionalized maleimide area to form a resulting array structure 617, which can be detectable and/or identified, according to a specific embodiment. Of course, there can be other variations, modifications, and alternatives.

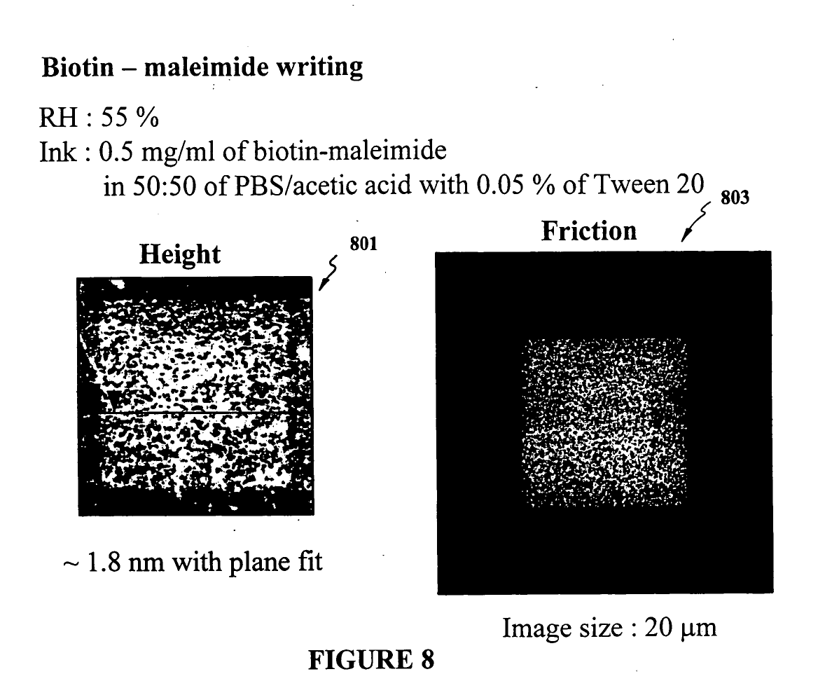

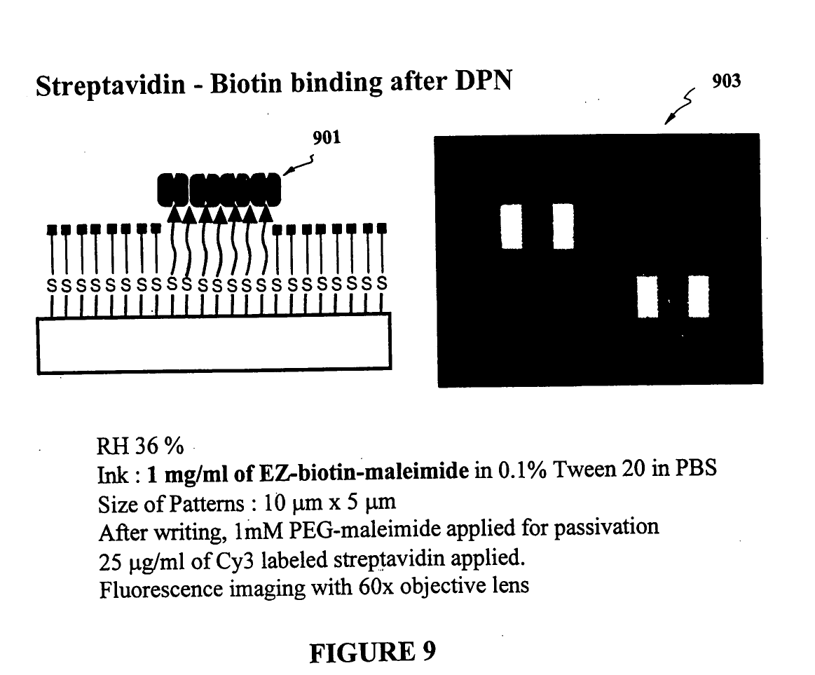

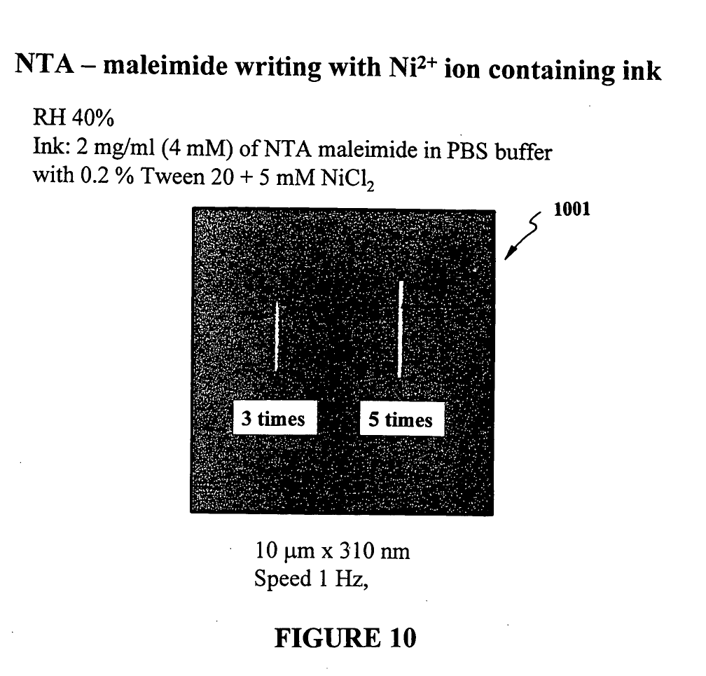

FIGS. 8 through 10 are simplified diagram illustrating experimental results according to embodiments of the present invention. This diagram is merely an example, which should not unduly limit the scope of the claims herein. One of ordinary skill in the art would recognize many variations, alternatives, and modifications. As merely an example, a pattern using biotin for maleimide write has been illustrated using FIG. 8. As shown, photograph 801 illustrates a height and photograph 803 illustrates a friction according to an embodiment of the present invention. FIG. 9 illustrates a streptavidin 901 formed region on functional groups according to a specific embodiment. A photograph of such region has been illustrated by reference numeral 903 according to a specific embodiment. An additional photograph 1001 of MTA maleimide writing with Ni2+ ion containing ink is also illustrated. As shown, the present method and system provides for printing (or writing) using a probe confirmation with ink including surfactant entity. Of course, there can be other variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims. Further details of these and other experiments can be found throughout the present specification and more particularly below.

### EXPERIMENTS

To prove the principles and operation of the present invention, we performed various experiments. These experiments have been used to demonstrate the invention and certain benefits associated with the invention. As experiments, they are merely examples, which should not unduly limit the scope of the claims herein. One of ordinary skill in the art would recognize many variations, alternatives, and modifications. Details of these experiments are provided below.

Before discussing the specific experimental results, we have provided certain reference information of Dip-Pen nanolithography, which we have uncovered. As merely an example Dip-Pen Nanolithography (DPN) has been a direct-write printing technique that uses chemically modified AFM tips to pattern materials on a variety of substrates at the nanoscale.¹ DPN was demonstrated by patterning self-assembled monolayers (SAMs) of alkylthiols on gold substrates.² Since then, the technique has evolved to include many other ink-substrate combinations. Examples of inks include solid-state materials,³ small molecules, polymers, dendrimers,⁶ DNA⁷ and proteins⁸. Metals,² semiconductors,⁹ insulators⁴ and organic thin films^{5, 7, 8} adsorbed on these surfaces have served as substrates. Although the details of the various ink-substrate chemistries employed differ from one system to the next, the ink deposition process in general depends on the solubility of the ink in the water meniscus that forms at the point of contact between the AFM tip and the substrate, the efficiency of activated transfer of the ink from the tip and its stability within the meniscus, and adsorption of the ink to the substrate surface.^{1, 9-11}

A majority of DPN experiments have used the thiol-on-gold system, where chemisorption of the thiol molecules on the gold surface is the driving force for ink transfer from the tip. Thiol molecules are not reactive with each other, but freely diffuse across previously chemisorbed regions until they become bound at the periphery to reactive gold sites, resulting in isotropic growth.¹ The driving force for deposition is thus strongly dependent on molecular diffusion along concentration gradients extending outward from the AFM tip to bare gold. This surface is highly polarizable and is completely wetting at all temperatures, due to the strong affinity the water/ink fluid has for gold. Under ambient conditions, water adsorbs on the gold surface to form a continuous liquid film of monolayer thickness with an equilibrium contact angle θ_{E}=0°.¹² Molecular diffusion of the ink from the tip in this case is not impeded by pinning of the fluid at the boundary separating the liquid, solid and vapor phases, as it would for a substrate surface that is not totally wetting (θ_{E}>0°).¹³ A non-wetting or partially wetting substrate surface presents an additional activation barrier to ink transport.

Direct patterning of biological materials such as DNA, peptides and proteins at the nanoscale without loss of activity requires the ability to immobilize these biomolecules through specific recognition chemistries that minimize nonspecific binding. Patterning biologically active proteins directly onto gold¹⁴ and nickel oxide^{15,16} surfaces using DPN in this manner has been demonstrated. Immobilization of biomolecules on oxidized silicon or glass substrates requires the incorporation of an adsorbed functional film that can act as a specific binding template. Recently, Mirkin's group described the direct writing of acrylamide-modified oligonucleotides onto oxidized silicon surfaces functionalized with 3′-mercaptopropyltrimethoxysilane (MPTMS) monolayers.⁷ The use of organofunctional silane chemistry such as MPTMS is a successful strategy for immobilizing biomolecules on glass and oxidized substrates that has been used extensively for fabricating DNA, small-molecule and protein micro-array chips.¹⁷

Organic thin films like MPTMS are less wettable than “high energy” surfaces, such as ionic, covalent or metallic materials. MPTMS-coated glass is partially hydrophobic; pure water forms a droplet on this surface with an equilibrium contact angle of 58°. While this may have minimal consequences at the micron length scale, it can have important ramifications for DPN. However, it is also reasonable that the charged and highly hydrophilic oligonucleotide inks used by Mirkin and coworkers actually increase the wettability of the substrate as it binds to the mercaptosilane surface, which facilitates the ink deposition process. It is well known that wetting of surfaces can be strongly influenced by molecular adsorption,¹⁸ a fact that has been discussed previously in the context of DPN.¹⁹ Further details of the present experiments can be found throughout the present specification and more particularly below. Again, these experiments are merely examples, which should not unduly limit the scope of the claims herein. One of ordinary skill in the art would recognize many variations, modifications, and alternatives.

In the present experiments, we demonstrate certain aspects of direct DPN writing according to embodiments of the present invention. More particularly, we have demonstrated DPN writing of the small-molecule ligand biotin on mercaptosilanized glass employing the functionalized linker molecule (+)-Biotinyl-3-maleimidopropionamidyl-3,6-dioxaoctanediamine (EZ-Link Maleimide PEO₂-Biotin, Pierce) as the ink. The fabrication of streptavidin or avidin nanostructures built upon DPN patterning of biotin represents a general route toward molecular recognition-mediated protein immobilization at the nanoscale due to the prevalence of biotin-tagged biomolecules. A stepwise procedure for functionalizing DPN-written SAMs of 16-mercaptohexadecanoic acid on gold with biotin has been published,²⁰ and we have shown that analogous molecular recognition chemistry can be applied to patterning glass substrates as well, by writing MPTMS ink onto clean glass followed by covalent attachment of biotin.⁴ However, successful patterning of the reactive MPTMS ink with DPN was limited to narrow operating conditions (e.g., low relative humidity, i.e., RH), due to polymerization of the alkoxysilane ink in the hydrated environment of the scanning AFM tip on the glass surface. Recently, the direct DPN writing of N-hydroxysuccinimide functionalized biotin onto polyethyleneimine-coated silicon oxide surfaces has been reported.²¹

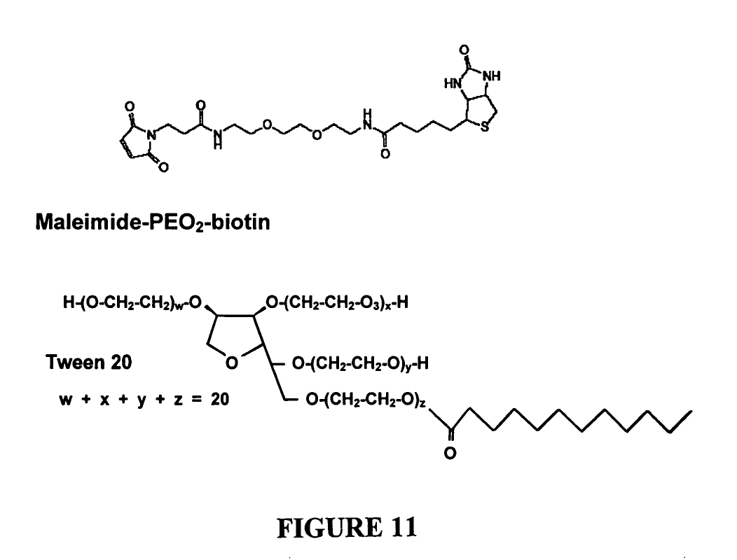

The coupling chemistry for maleimide is similar to that for acrylamide-modified DNA:⁷ both react with the pendant thiol groups of MPTMS by conjugate addition to form stable thioether bonds. In addition, the maleimide PEO₂-biotin molecule is soluble in aqueous solutions (≧25 mg/mL) due to the polyethylene oxide (PEO₂) spacer arm. Therefore, we expected that the biotin-maleimide linker molecule would perform comparably to acrylamide-DNA as an ink for DPN. However, we were not able to obtain consistent patterning of the maleimide-PEO₂-biotin ink, even at relative humidity (RH) values above 90%. Examples of the malemide PEO₂-biotin molecule is illustrated by way of FIG. 11.

The addition of small amounts of the nonionic surfactant Tween-20 (Sigma) to the ink (as little as 50 ppm by volume) activated the transfer of the biotin linker molecule from the AFM tip to the MPTMS-coated substrate, enabling us to directly pattern biotin routinely with sub-100 nm resolution, and at moderate relative humidity values (RH=50-65%). An example of the Tween-20 is also illustrated by FIG. 11. Tween-20 (polyoxyethylene sorbitan monolaurate) is a nondenaturing, nonionic detergent that is commonly used to suppress nonspecific reactions between antibodies, antigens and other biomolecules.^{22,23} It has also been used as a solubilizer in membrane chemistry.²⁴ Tween-20 has proven effective in blocking nonspecific binding of biomolecules to hydrophobic surfaces, such as carbon nanotubes.²⁵ The degree to which detergents such as Tween-20 can perform these functions is based on their ability to bind to hydrophobic surfaces in aqueous solution.²⁶

We believe the inclusion of Tween-20 in the ink for DPN activates biotin writing primarily by increasing the wettability of the ink on the MPTMS substrate. This in turn increases the driving force for ink transport from the AFM tip due to increased accessibility of maleimide PEO₂-biotin to the thiol groups of MPTMS. The biotin written areas were functional for subsequent immobilization of fluorescently labeled streptavidin with minimal nonspecific binding. We also immobilized avidin-linked horseradish peroxidase enzymes to biotin-written areas on silanized glass and directly characterized enzymatic activity from the sites with a fluorescence-based assay involving conversion of fluorogenic substrate molecules to fluorescent products (see Supporting Information).

Glass substrates (VWR #1 coverslips) were cleaned by standard methods²⁷ and coated with MPTMS monolayers by a two-step silanization procedure which involved an intermediate water treatment.²⁸ Clean glass coverslips were silanized via evaporation from a 2 μL drop of neat liquid MPTMS (Aldrich) at 120° C. for 10 minutes in a covered 150 mL glass jar, followed by extensive washing with deionized water (Millipore Gradient). After drying with nitrogen gas, the glass coverslips were further silanized for an additional 10 minutes with a fresh 2 μL drop of MPTMS under the same conditions. Silanized glass coverslips were cured at 100° C. for 16 hours and used as substrates for DPN writing.

Commercially available AFM tips (silicon nitride cantilever, 0.58 N/m, Digital Instruments) were cleaned with “piranha” solution (3:7 (v/v) mixture of 30% H₂O₂ and H₂SO₄) (caution: this mixture reacts violently with organic materials) for 30 minutes at room temperature, rinsed copiously with deionized water (Millipore Gradient) and dried at 100° C. MPTMS was evaporated onto the clean tips at 120° C. for 30 minutes to facilitate ink adsorption on the AFM tip surface. The tips were then dipped for 10 minutes into ink solutions consisting of maleimide PEO₂-biotin (25 mg/mL) and varying concentrations of Tween-20 (from 0 to 0.1% v/v) dissolved in phosphate-buffered saline (PBS, pH=7.2-7.4), blow-dried with compressed nitrogen gas, and used immediately for DPN.

DPN experiments were performed using a Multimode AFM (Nanoscope IV controller) from Digital Instruments in a large glove bag purged with nitrogen gas which was either bubbled through water or passed through a dessicant. The RH, measured with a digital hygrometer, was controlled in this way from 22% to 92%. All experiments were performed in contact mode at room temperature between 23 and 24° C. Patterns were imaged by lateral force microscopy (LFM) or tapping mode AFM immediately after writing.

Without Tween-20 included in the DPN ink, biotin patterns were not observed on MPTMS-coated substrates below 80% RH. Biotin patterns could be imaged by LFM after increasing the RH up to 92%, but the patterns were not reproducible and the spatial resolution was poor. Systematic variation of other DPN parameters, such as tip speed and tip-surface contact force, did not improve ink transport.

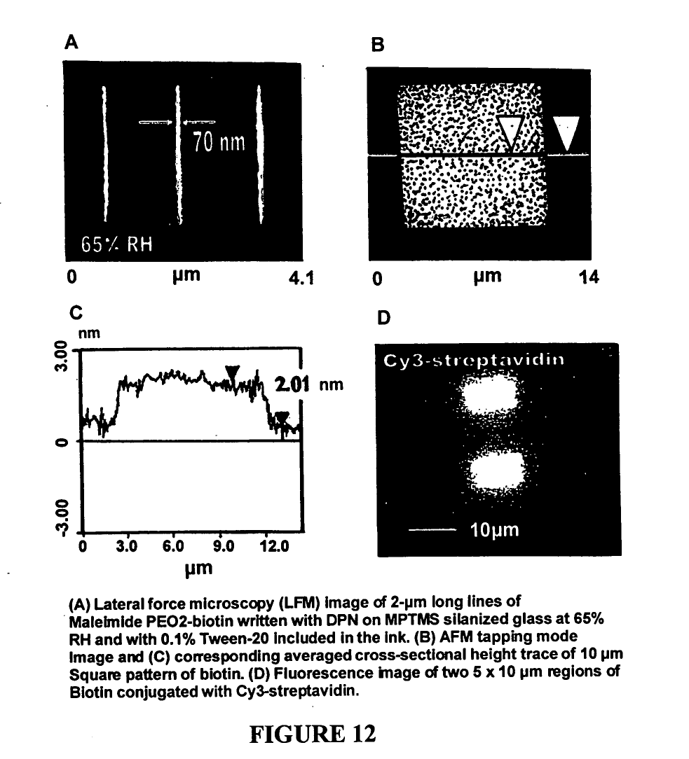

As merely an example, FIG. 12 (including FIGS. 12A, 1B, 12C, and 12D) illustrates certain experimental results in diagrams according to embodiments of the present invention. These diagrams are merely illustrations, which should not unduly limit the scope of the claims herein. One of ordinary skill in the art would recognize many variations, modifications, and alternatives. Referring to FIG. 12A,” we have illustrated a lateral force microscopy (LFM) image of 2-μm long lines of maleimide PEO2-biotin written with DPN on MPTMS silanized glass at 65% RH and with 0.1% Tween-20 included in the ink. As shown, the long lines are clean and have little variation, which demonstrates the present methods and systems according to specific embodiments. We have also illustrated an AFM tapping mode image, which has been illustrated by FIG. 12B. FIG. 12C illustrates a plot of height (measured in nanometers) against width (also measured in nanometers). The plot corresponds an averaged cross-sectional height trace of 10 μm square pattern of biotin. As shown, the averaged height is consistent and has good uniformity, which also demonstrates the present methods and systems according to embodiments of the present invention. We also illustrated via FIG. 1D a fluorescence image of two 5×10 μm regions of biotin conjugated with Cy3-streptavidin, which illustrates sharp lines for the present patterns, according to embodiments of the present invention. Of course, there can be other variations, modifications, and alternatives.

The addition of Tween-20 to the ink did not diminish the maleimide-thiol reactivity for the range of concentrations used²⁹ and facilitated direct biotin patterning with DPN. FIG. 1A shows an LFM image of three 2 μm-long lines of maleimide PEO₂-biotin written with a tip speed of 0.4 μm/sec at 65% RH, with 0.1% Tween-20 included in the ink. In the LFM images, written areas are brighter than the more hydrophobic silanized glass background, indicating an increase in friction between the tip and these areas. The average width of the patterns was 70 nm. Patterns could be written for several hours with no noticeable changes in feature appearance or size. FIG. 1B shows the tapping mode topographic image of a 10 μm square pattern of maleimide PEO₂-biotin, while FIG. 12C shows an average of cross-sectional traces of the height taken perpendicularly to the top of the pattern. Although the measured height of the deposited maleimide PEO₂-biotin (2.05 nm) was less than the fully extended spacer arm length of the maleimide PEO₂-biotin molecule (2.91 nm, Pierce), it indicated that maleimide PEO₂-biotin was most likely deposited as a monolayer.

FIG. 12D is a fluorescence image of Cy3-streptavidin conjugated to two 2.5 μm×10 μm patterned regions of maleimide PEO₂-biotin. The patterns were written with a scanning speed of 10 μm/sec and at 70% RH. Before the Cy3-streptavidin was introduced, unpatterned regions of the mercaptosilanized glass surface were passivated with a 1 mM solution of PEG-maleimide in PBS buffer (O-(2-Maleimidoethyl)-O′-methyl-polyethylene glycol, MW 5000, purity >90%, Fluka) to prevent nonspecific binding of proteins. The sample was then incubated for 10 minutes using 2 μg/ml of Cy3-streptavidin in PBS buffer with 0.02% (v/v) Tween 20. After exhaustively washing the patterned samples in PBS buffer containing 0.1% Tween 20, the sample was rinsed with Milipore water and dried under N₂ gas. Fluorescence was observed using an inverted epi-fluorescence microscope with a Hg/Xe arc lamp (Eclipse TE 300, Nikon). Images of fluorescent patterns were captured with a high-resolution, Peltier-cooled CCD camera (e.g., CoolSnap-HQ, Roper Scientific). The degree of nonspecific binding of Cy3-streptavidin was minimal compared to previous results reported by us' and others,²¹ as indicated by the fluorescence intensity from the patterned regions relative to the background.

Systematic variation of the Tween-20 concentration in the ink and RH was performed to find the optimum conditions for patterning the biotin linker molecules on MPTMS. We found that concentrations of surfactant as low as 0.005% and at RH values as low as 40% would result in transfer of biotin to the surface, after a time delay of about 1 minute. Included in the supporting information are data that show the minimum RH needed to observe biotin deposition onto MPTMS for Tween-20 concentrations ranging from 0.005% to 0.1%. The minimum RH needed for biotin writing scaled inversely with surfactant concentration; with 0.1% surfactant in the ink, the minimum RH was 22%.

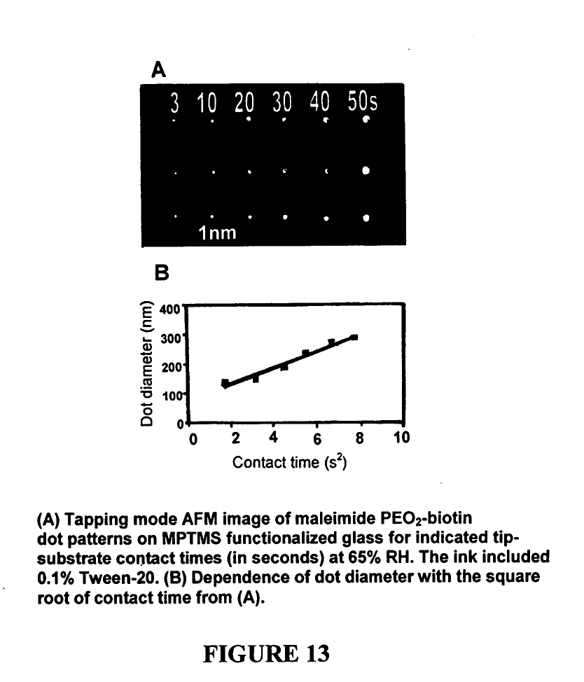

Higher RH values at a given concentration of Tween-20 resulted in increased diffusion rates, as did increased surfactant concentrations in the ink for a given value of the RH. The optimal conditions for surfactant-mediated biotin writing were 0.1% Tween-20 at 50-65% RH. Under these conditions, biotin deposition occurred immediately on contact. The growth of feature size with contact time had the characteristic square root time dependence indicative of growth by isotropic molecular diffusion.³⁰ FIG. 13A is a tapping mode AFM image of biotin dot patterns on MPTMS-functionalized glass for increasing tip-substrate contact times at 65% RH. The dependence on contact time is shown in FIG. 13B. These results suggest that the relative concentration of Tween-20 can be systematically varied in addition to other parameters, such as RH, temperature, scan speed and force, to control the deposition of ink in DPN. Increased Tween-20 concentration in the ink beyond 0.1% did not result in improved performance.

Control experiments were performed with DPN using AFM tips coated with either maleimide PEO₂-biotin or Tween-20, but not both. LFM data from these experiments are included in the supporting information. The biotin ink could be transferred from the coated AFM tip and patterned on hydrophilic clean glass (not silanized) at 45% RH, which is consistent with the high solubility of the molecule and suggests that dissolution of the ink from the AFM tip into the water meniscus is not the limiting barrier for DPN writing. In this case, the biotin was weakly physisorbed to the glass surface, and the patterns blurred with repeated LFM scans. In a separate experiment, Tween-20 (0.1%) without biotin was patterned with DPN onto MPTMS-coated glass. LFM images of the patterns were similar in appearance to those of maleimide PEO₂-biotin with surfactant, except that the rate of deposition of Tween-20 alone was considerably faster than when biotin was also included in the ink. This indicates that adsorption of surfactant to the substrate plays an important role in activating biotin writing with DPN. PEO-based detergents similar to Tween-20 adsorb readily to silanized silica surfaces of comparable wettability (same contact angle) to our MPTMS-coated substrate, as determined by an in-situ ellipsometry study.³¹

To learn more about how surfactant activates DPN writing of biotin, we measured the surface tension and contact angles of maleimide PEO₂-biotin inks with varying amounts of Tween-20 on MPTMS-coated glass surfaces. We also measured the contact angles of pure water droplets on MPTMS-glass surfaces that were “inked” with maleimide PEO7-biotin and different amounts of Tween-20 in PBS buffer and dried to simulate the wetting of an inked AFM tip by the water meniscus.

The dynamics governing molecular transport in DPN are complex and not well understood, but they will depend on balances between adhesive and cohesive intermolecular forces at the coated AFM tip, the water meniscus, and the substrate. The strength of attraction of a fluid to a solid depends on the relative energies at the solid-vapor, the liquid-vapor, and the solid-liquid interfaces, which can be determined with high sensitivity by measuring contact angles and interfacial tensions.¹⁸ Although these measurements are typically carried out at the macroscopic scale, they are extremely sensitive to intermolecular forces that operate at the nanoscale,³² and so are useful for understanding how Tween-20 activates DPN writing, even though the dynamics occurring at the AFM tip cannot be directly measured.

Contact angles of sessile drops on a MPTMS-coated glass substrate of aqueous solutions having the same composition as the inks used were estimated visually with a contact angle goniometer (Rame-Hart). For these measurements, the goniometer stage was enclosed in a large glove bag and the RH was kept saturated at 100% to prevent evaporation from the drops over time.³³ Contact angle measurements of pure water on dry coated surfaces emulating an inked AFM tip quickly equilibrated within a few seconds and could be performed at ambient RH. The liquid-vapor surface tensions (γ_{LV}) of pure water (Millipore) and PBS buffer solutions containing increasing amounts of Tween-20 (0-0.1%) and 25 mg/mL biotin were determined using the pendant drop technique, since this could be carried out with −50 μL volumes and consumed small amounts of the expensive biotin reagent. Images of pendant drops were captured with a digital camera, and fit with an axisymmetric drop shape analysis program³⁴ to give the surface tension (see Supporting Information). As a check, the surface tensions of solutions lacking biotin were also measured with a Wilhelmy plate tensiometer (Nima Corporation). Values for the surface tension obtained using the two techniques agreed to within the uncertainty in the measurements.

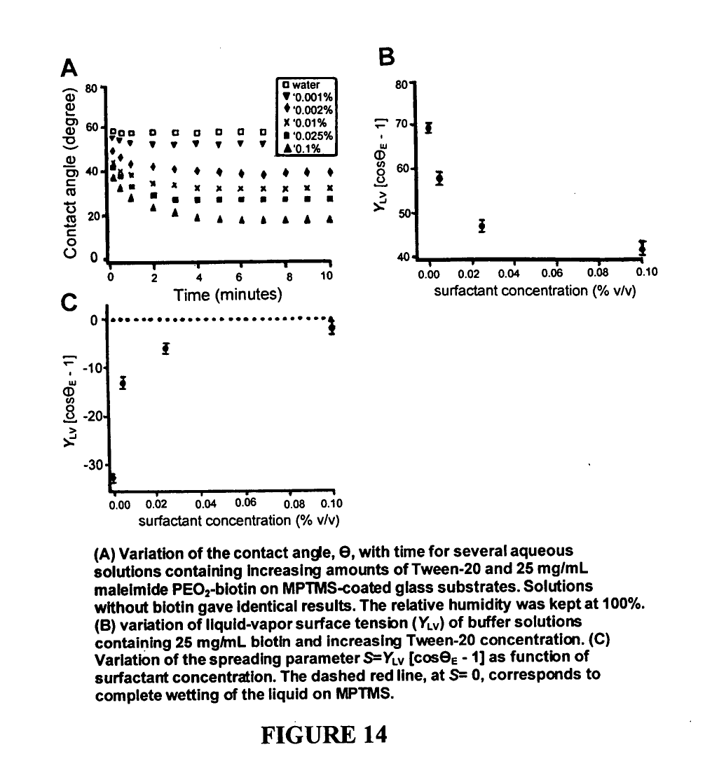

FIG. 14A is a plot of contact angles (θ) taken over 10 minutes of several aqueous solutions that served as models for biotin and Tween-20 DPN inks on MPTMS-glass substrates.³⁵ The entry labeled “water” in the legend was for pure Millipore water (with or without biotin), while all of the other solutions were composed of PBS buffer with the indicated concentration (% v/v) of Tween-20. Each data point for all curves was taken from the average of 6 trials taken at different locations on the substrate. The maximum standard deviation in θ was 1.6° but was typically less than 1.0°. Importantly, the data were exactly identical for all the solutions whether or not 25 mg/mL biotin was included, which indicates that the biotin molecule is not surface active. The contact angles relaxed over the course of several minutes to lower values, which did not change further with time. The change in contact angle increased with increasing surfactant concentration. There was no change in the contact angle for water (θ=58°) over 10 minutes, with or without 25 mg/mL biotin, while the contact angle decreased by 20 degrees for the solution containing 0.1% surfactant.

While the contact angles in FIG. 14A took several minutes to equilibrate and never dropped below approximately 20°, the contact angles of drops of pure water on dry surfaces emulating inked AFM tips quickly equilibrated (within seconds) to near-zero values (for 0.1% Tween-20), suggesting that the water meniscus, once formed, completely wetted the tip (see Supporting Information).

FIG. 14B shows the change in liquid-vapor surface tension (γ_{LV}) of buffer solutions containing 25 mg/mL biotin and various amounts of Tween-20. Each data point is the average of four to six trials taken from separate identically prepared solutions with ± one standard deviation indicated by error bars. A transition in the slope of γ_{LV} versus surfactant concentration occurs in the region corresponding to the critical micelle concentration (cmc) for Tween-20 (0.007% v/v).²⁶

FIG. 14C shows the dependence of the surfactant concentration on the spreading parameter, S. The spreading parameter is the energy difference per unit area of a substrate when dry versus wet and is given by the expression S=γ_{SV}−[γ_{SL}+γ_{LV}], where the surface tensions in the expression are at the solid-vapor, solid-liquid and liquid-vapor interfaces, respectively.¹³ The sign of S determines whether or not a liquid will completely wet a surface. When S≧0, the liquid completely spreads over the substrate as a nanometer-thick film (θ_{E}=0°), while S<0 corresponds to the liquid partially wetting the surface and forming a droplet at equilibrium with a nonzero contact angle. The three coefficients in the expression for S are related by Young's equation: γ_{LV} cos θ_{E}=γ_{SV}−γ_{SL}.³⁶ By substitution, the spreading parameter can be determined experimentally from S=γ_{LV} (cos θ_{E}−1), where θ_{E} values are the contact angles versus Tween-20 concentration measured at 10 minutes in FIG. 3a, and γ_{LV} are the corresponding surface tension values measured from aqueous solutions of the same compositions, shown in FIG. 14B.

For spreading (wetting) to occur, [γ_{SL}+γ_{LV}] must be made small relative to γ_{SV}. For highly hydrophilic substrates commonly used in DPN, such as gold, NiO or SiO₂, γ_{SV} exceeds [γ_{SL}+γ_{LV}]. Water-based inks will completely wet these substrates (θ_{E}=0°). Tween-20 promotes spreading of the ink on the partially hydrophobic MPTMS substrate (θ_{water}=58°) by adsorption at both the solid-liquid (γ_{SL}) and liquid-vapor (γ_{LV}) interfaces, which lowers these surface tensions. This is exactly how a surfactant functions as a detergent (an agent that can remove or prevent binding of foreign material by surface chemistry). The mechanism by which Tween-20 minimizes nonspecific binding of proteins to hydrophobic surfaces is fundamentally the same as how it promotes adhesion of water molecules onto MPTMS, through preferential adsorption at the solid-aqueous phase and aqueous-hydrophobic phase interfaces (either air or an “oily phase” such as the hydrophobic domains on the surface of a protein). ¹⁸

In summary, we have demonstrated that the inclusion of a small amount of the detergent Tween-20 lowers an activation barrier for ink adsorption to MPTMS surfaces by lowering the surface tension at both the liquid-vapor and solid-liquid interfaces, thereby increasing the wettability of the substrate. This in turn increases the driving force for ink transport from the AFM tip due to increased chemisorption of maleimide-biotin to the thiol groups of MPTMS. The increased wettability of the substrate also likely stabilizes the water meniscus,³⁰ which would act to further facilitate ink transport, although we cannot test this directly. It is also possible that the detergency of Tween-20 aids in the dissolution of biotin from the AFM tip into the water meniscus, although the evidence suggests this is not as important an effect.

Biotin deposition from the coated AFM tip to MPTMS can be activated by as little as 0.005% v/v (50 ppm) of Tween-20 in the ink, although reliable patterning under ambient conditions occurs at higher surfactant concentrations in the range 0.05-0.1%, which is about an order of magnitude greater than the cmc. Without Tween-20 in the ink, reliable patterning of maleimide-biotin on MPTMS with DPN was impossible. The actual local fluxes and concentrations of Tween-20 and maleimide PEO₂-biotin in the water meniscus in DPN are unknown, and may be very different from the composition of the as-prepared ink solutions. We have shown unequivocally however, that increasing the relative amount of Tween-20 leads to improved wettability of the MPTMS substrate, and that this correlates with the activation of direct biotin writing with DPN. On one level, this is a useful result since the direct patterning of biotin by DPN provides a universal platform for molecular recognition mediated protein immobilization on glass and silicon oxide surfaces. However, the significance of including detergent additives to DPN inks extends beyond biotin conjugation chemistry.

Surfactants are extensively used in macroscopic coating applications, for example, in optimizing how paints and inkjet inks wet and spread on various media.¹⁸ These experiments describe an analogous application at the nanoscale, which we have discovered. The systematic exploration of surfactant additives to inks for DPN may represent a useful strategy for controlling the writing of biological molecules on previously inaccessible or difficult to pattern substrates. Organic solvents that have been used to ink AFM tips (such as acetonitrile for alkylthiols and dimethylformamide for DNA) may serve to facilitate ink transport in certain cases by leaving behind residues (even after the tips had been dried) that can dissolve in the nascent water meniscus. These volatile compounds can form surface tension gradients in water that can drive ink transport from the tip due to convection. However, these effects are not likely to be consistent or reproducible as the cosolvent evaporates, and we do not know of any work that has sought to systematically control them for DPN. Although the local concentration of Tween-20 in the meniscus is not known, Tween-20 is nonvolatile. A large number of surfactants and detergents have been developed as tools for biological research, resulting in a wide range of chemical and physical properties that can be selected and optimized for a particular application, such as crystallization of membrane bound proteins.³⁷ We believe that these compounds can be used in a new role: as additives to facilitate the direct patterning of biological macromolecules on select substrates with scanning probe nanolithography.

### REFERENCES

1. Ginger, D. S.; Zhang, H.; Mirkin, C. A. Angew. Chem. Int. Ed. 2004, 43, 30.
2. Piner, R. D.; Zhu, J.; Xu, F.; Hong, S. H.; Mirkin, C. A. Science 1999, 283, 661.
3. Fu, L.; Liu, X. G.; Li, S. Y.; Dravid, V. P.; Mirkin, C. A. Nano Lett. 2003, 3, 757.
4. Jung, H.; Kulkarni, R.; Collier, C. P. J. Am. Chem. Soc. 2003, 125, 12096.
5. Lim, J.-H.; Mirkin, C. A. Adv. Mat. 2002, 14, 1474.
6. McKendry, R.; Huck, W. T.; Weeks, B.; Fiorini, M.; Abell, C.; Rayment, T. Nano Lett. 2002, 2, 713.
7. Demers, L. M.; Ginger, D. S.; Park, Si.; Li, Z.; Chung, S. W.; Mirkin, C. A. Science 2002, 296, 1836.
8. Lim, J. H.; Ginger, D. S.; Lee, K. B.; Heo, J.; Nam, J. M.; Mirkin, C. A. Angew. Chem. Int. Ed. 2003, 42, 2309.
9. Ivanisevic, A.; Mirkin, C. A. J. Am. Chem. Soc. 2001, 122, 7887.
10. Weeks, B. L.; Noy, A.; Miller, A. E.; De Yoreo, J. J. Phys. Rev. Lett. 2002, 88, 25505.
11. Rozhok, S.; Piner, R.; Mirkin, C. A. J. Phys. Chem. B. 2003, 107, 751.
12. Jang, J.; Schatz, G. C.; katner, M. A. J. Chem. Phys. 2002, 116, 3815.
13. de Gennes, P.-G.; Brochard-Wyart, F.; Quere, D. Capillarity and Wetting Phenomena: Drops, Bubbles, Pearls, Waves; Springer-Verlag: New York, 2004.
14. Lee, K. B.; Lim, J. H.; Mirkin, C. A. J. Am. Chem. Soc. 2003, 125, 5588.
15. Nam, J.-M.; Han, S. W.; Lee, K.-B.; Liu, X.; Ratner, M. A.; Mirkin, C. A. Angew. Chem. Int. Ed. 2004, 43, 1246, and supporting information.
16. Agarwal, G.; Naik, R. R.; Stone, M. O. J. Am. Chem. Soc. 2003, 125, 7408.
17. Pirrung, M. C. Angew. Chem. Int. Ed. 2002, 41, 1276.
18. Adamson, A. W.; Gast, A. P. Physical Chemistry of Surfaces; 6^{th} ed., Wiley: New York, 1997.
19. Hong, S.; Zhu, J.; Mirkin, C. A. Langmuir 1999, 15, 7897.
20. Hyun, J.; Ahn, Si.; Lee, W. K.; Chilkoti, A.; Zauscher, S. Nano Lett. 2002, 2, 1203.
21. Pena, D. J.; Raphael, M. P.; Byers, J. M. Langmuir 2003, 19, 9028.
22. Thean, E. T.; Toh, B. H. Anal. Biochem. 1989, 177, 256.
23. Tovey, E. R.; Ford, S. A.; Baldo, B. A. Electrophoresis 1989, 10, 243.
24. Lund, S.; Orlowski, S.; de Foresta, B.; Champeil, P.; le Maire, M.; Moller, J. V. J. Bio. Chem. 1989, 264, 4907.
25. Chen, R. J.; Bangsaruntip, S.; Drouvalakis, K. A.; Kam, N. W. S.; Shim, M.; Li, Y.; Kim, W.; Utz, P. J.; Dai, H. Proc. Nail. Acad. Sci. USA 2003, 100, 4984.
26. Sigal, G. B.; Mrksich, M.; Whitesides, G. M. Langmuir 1997, 13, 2749.
27. Kern, W. J. Electrochem. Soc. 1990, 137, 1887.
28. Krasnoslobodtsev, A. V.; Smirnov, S. N. Langmuir 2002, 18, 3181.
29. Certain control experiments were performed by reacting equivalent amounts of maleimide PEO₂-biotin on MPTMS-functionalized glass coverslips with varying amounts of Tween-20 (0.005-0.1%), followed by incubation with Cy3-streptavidin. Integration of the resultant fluorescence intensities showed that the inclusion of surfactant in this range of concentrations did not affect the binding of the maleimide to the thiol groups on the surface.
30. Jang, J.; Hong, S.; Schatz, G. C.; Ratner M. A. J. Chem. Phys. 2001, 115, 2721.
31. Welin-Klintstrom, S.; Askendal, A.; Elwing, H. J. Colloid Interface Sci. 1993, 158, 188.
32. Israelachvili, J. Intermolecular and Surface Forces; ^{2nd} ed., Academic Press: London, 1992.
33. Holmes-Farley, S. R.; Reamey, R. H.; McCarthy, T. J.; Deutch, J.; Whitesides, G. W. Langmuir 1985, 1, 725.
34. Busoni, L.; Carla, M.; Lanzi, L. Rev. Sci. Instrum. 2001, 72, 2784.
35. The contact angle values reported here were “stationary”: the drops were not externally forced to advance or recede. Measured values of the advancing and receding contact angles of pure water on MPTMS were θ_{A}=63° and θ_{R}=36°, indicating moderately large contact angle hysteresis, probably due to chemical heterogeneity in the MPTMS monolayer. The stationary contact angle for water, θ=58°, was close to the advancing angle.
36. Young, T. Philos. Trans. Soc. London 1805, 95, 65.
37. Garavito, R. M.; Ferguson-Miller, S. J. Biol. Chem. 2001, 276, 32403.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method for forming one or more nano-sized patterns using one or more molecule species overlying a substrate structure, the method comprising:
applying a probe tip within a vicinity of a first spatial region of a surface region of a substrate member, the substrate member being characterized by a first characteristic, the probe tip being in a direction toward the spatial region on the surface region;
transferring one of more of a plurality of molecules characterized by a second characteristic through a fluid medium comprising one or more surfactant species overlying the spatial region via the probe tip provided within the vicinity of the spatial region of the surface region, the one or more surfactant species causing one or more of the plurality of molecules characterized by the second characteristic to be deposited overlying the first spatial region, the first characteristic being different from the second characteristic; and
moving the probe tip from the vicinity of the first spatial region to a vicinity of a second spatial region on the surface region while continuing to deposit one or more of the plurality of molecules characterized by the second characteristic through the fluid medium comprising one or more surfactant molecules.

2. The method of claim 1 wherein the first characteristic is hydrophobic.

3. The method of claim 1 wherein the first characteristic is partially hydrophobic.

4. The method of claim 1 wherein the first characteristic is hydrophilic.

5. The method of claim 1 wherein the first characteristic is partially hydrophilic.

6. The method of claim 1 wherein the substrate is made of a material selected from glass, quartz, plastic, silicon, metal, mica, and ITO.

7. The method of claim 1 wherein the surface region comprises an overlying layer to provide the first characteristic.

8. The method of claim 1 wherein the probe tip is characterized by a size of about 30 nanometers and less.

9. The method of claim 1 wherein the first spatial region is characterized by a size of about 70 nanometers and less.

10. The method of claim 1 wherein probe tip is on and in contact with the first spatial region; and wherein the probe tip is on and in contact with the second spatial region.

11. The method of claim 1 wherein the surface region comprises an overlying layer of silane bearing species.

12. The method of claim 11 wherein the one or more plurality of molecules comprises a plurality of biotin entities.

13. The method of claim 1 wherein the one or more plurality of molecules comprise a plurality of biotin linker molecules; wherein the surface region comprises MPTMS; and wherein the one or more surfactant species comprises a non-denaturing, non-ionic detergent.

14. The method of claim 1 wherein the one or more surfactant species activates a transfer of the one or more molecules onto the first region.

15. The method of claim 1 wherein the one or more surfactant species is provided at a predetermined concentration to facilitate the transfer of the one or more molecules onto the first region.

16. The method of claim 1 further comprising maintaining the substrate in an environment having a relative humidity ranging from about 22% to about 92% during the transferring of the one or more molecules.

17. The method of claim 1 further comprising maintaining the substrate in an environment having a relative humidity of more than about 22% during the transferring of the one or more molecules.

18. The method of claim 1 wherein the moving is characterized by a rate of about 0.0004 and greater millimeters per second.

19. The method of claim 1 further comprising subjecting the probe tip to the one or more molecules in the fluid medium including the one or more surfactant species there.

20. The method of claim 19 wherein the fluid medium including the one or more molecules and the surfactant species are derived from a reservoir.

21. The method of claim 1 wherein the probe tip is maintained at a contact force overlying the first spatial region at about 9 nN to about 25 nN.

22. The method of claim 1 wherein the probe tip is maintained at a contact force overlying the first spatial region greater than about 9 nano Newton.

23. The method of claim 1 wherein the substrate is maintained at a temperature ranging from about 23° C. to about 24° C.

24. A system for forming one or more molecular patterns using one or more molecule species overlying a substrate structure, the method comprising:
a stage assembly operable to maintain a substrate member comprising a surface region, the substrate member being characterized by a first characteristic;
a sample reservoir operably coupled to the stage assembly, the sample reservoir comprising a plurality of molecules having a second characteristic and a plurality of surfactant species mixed within the plurality of molecules in a fluid medium;
a probe tip operably coupled to the stage, the probe tip being adapted to transfer one or more of the plurality of molecules including one or more of the surfactant species through the fluid medium from the fluid medium in the sample reservoir, the probe tip being adapted to apply the probe tip within a vicinity of a first spatial region of the surface region of the substrate member and adapted to transferring one of more of the plurality of molecules through a portion of the fluid medium comprising one or more surfactant species overlying the spatial region via the probe tip provided within the vicinity of the spatial region of the surface region, the one or more surfactant species causing one or more of the plurality of molecules characterized by the second characteristic to be deposited overlying the first spatial region, the first characteristic being different from the second characteristic.

25. The system of claim 24 wherein the first characteristic is hydrophobic.

26. The system of claim 24 wherein the first characteristic is partially hydrophobic.

27. The system of claim 24 wherein the first characteristic is hydrophilic.

28. The system of claim 24 wherein the first characteristic is partially hydrophilic.

29. The system of claim 24 wherein the substrate is made of a material selected from glass, quartz, plastic, silicon, metal, mica, and ITO.

30. The system of claim 24 wherein the surface region comprises an overlying layer to provide the first characteristic.

31. The system of claim 24 wherein the probe tip is characterized by a size of about 30 nanometers and less.

32. The system of claim 24 wherein the first spatial region is characterized by a size of about 70 nanometers and less.

33. The system of claim 24 wherein probe tip is on and in contact with the first spatial region.

34. The method of claim 24 wherein the surface region comprises an overlying layer of silane bearing species.

35. The system of claim 24 wherein the one or more plurality of molecules comprises a plurality of biotin entities.

36. The system of claim 24 wherein the one or more plurality of molecules comprise a plurality of biotin linker molecules; wherein the surface region comprises MPTMS; and wherein the one or more surfactant species comprises a non-denaturing, non-ionic detergent.

37. The system of claim 24 wherein the one or more surfactant species activates a transfer of the one or more molecules onto the first region.

38. The system of claim 24 wherein the one or more surfactant species is provided at a predetermined concentration to facilitate the transfer of the one or more molecules onto the first region.

39. The system of claim 24 the substrate is maintained in an environment having a relative humidity ranging from about 22% to about 92%.

40. The system of claim 24 the substrate is maintained in an environment having a relative humidity of more than about 22%.

41. The system of claim 24 wherein the stage assembly is operable to move the substrate a rate of about 0.0004 and greater millimeters per second.

42. The system of claim 24 wherein the probe tip is maintained at a contact force overlying the first spatial region at about 9 nN to about 25 nN.

43. The system of claim 24 wherein the probe tip is maintained at a contact force overlying the first spatial region greater than about 9 nano Newton.

44. The system of claim 24 wherein the substrate is maintained at a temperature ranging from about 23° C. to about 24° C.

45. A method for forming one or more molecular patterns, using one or more surfactant entities, overlying a substrate structure, the method comprising:
applying a probe tip within a vicinity of a first spatial region of a surface region of a substrate member;
maintaining a volume of fluid including a plurality of molecules and a plurality of surfactant species coupled to the probe tip; and
causing a transfer of one of more of the plurality of molecules, using one or more surfactant species, overlying the spatial region via the probe tip provided within the vicinity of the spatial region of the surface region.

46. The method of claim 45 wherein the surface region comprises an overlying layer to provide the first characteristic.

47. The method of claim 45 wherein the probe tip is characterized by a size of about 30 nanometers and less.

48. The method of claim 45 wherein the first spatial region is characterized by a size of about 70 nanometers and less.

49. The method of claim 45 wherein probe tip is on and in contact with the first spatial region; and wherein the probe tip is on and in contact with the second spatial region.

50. The method of claim 45 wherein the surface region comprises an overlying layer of silane bearing species.

51. The method of claim 50 wherein the one or more plurality of molecules comprises a plurality of biotin entities.

52. The method of claim 45 wherein the one or more plurality of molecules comprise a plurality of biotin linker molecules; wherein the surface region comprises MPTMS; and wherein the one or more surfactant species comprises a non-denaturing, non-ionic detergent.

53. The method of claim 45 wherein the one or more surfactant species activates a transfer of the one or more molecules onto the first region.

54. The method of claim 45 wherein the one or more surfactant species is provided at a predetermined concentration to facilitate the transfer of the one or more molecules onto the first region.

55. The method of claim 45 further comprising maintaining the substrate in an environment having a relative humidity ranging from about 22% to about 92% during the transferring of the one or more molecules.

56. The method of claim 45 further comprising maintaining the substrate in an environment having a relative humidity of more than about 22% during the transferring of the one or more molecules.

57. The method of claim 45 wherein the moving is characterized by a rate of about 0.0004 and greater millimeters per second.

58. The method of claim 45 further comprising subjecting the probe tip to the one or more molecules in the fluid medium including the one or more surfactant species there.

59. The method of claim 58 wherein the fluid medium including the one or more molecules and the surfactant species are derived from a reservoir.

60. The method of claim 45 wherein the probe tip is maintained at a contact force overlying the first spatial region at about 9 nN to about 25 nN.

61. The method of claim 45 wherein the probe tip is maintained at a contact force overlying the first spatial region greater than about 9 nano Newton.

62. The method of claim 45 wherein the substrate is maintained at a temperature ranging from about 23° C. to about 24° C.
